(19) United States
(12) Patent Application Publication
(10) Pub. No.: US 2024/0297192 A1
(43) Pub. Date: Sep. 5, 2024

(54) SOLID-STATE IMAGE CAPTURING DEVICE AND MANUFACTURING METHOD, AS WELL AS ELECTRONIC DEVICE

(71) Applicant: SONY SEMICONDUCTOR SOLUTIONS CORPORATION, Kanagawa (JP)

(72) Inventor: Shigehiro IKEHARA, Kanagawa (JP)

(73) Assignee: SONY SEMICONDUCTOR SOLUTIONS CORPORATION, Kanagawa (JP)

(21) Appl. No.: 18/573,152

(22) PCT Filed: Feb. 10, 2022
(86) PCT No.: PCT/JP2022/005254

§ 371 Date: Dec. 21, 2023

(30) Foreign Application Priority Data
Jun. 30, 2021 (JP) 2021-108839

(51) Int. Cl. H01L 27/146

(52) U.S. Cl. CPC H01L 27/14623; H01L 27/14625; H01L 27/1463; H01L 27/14685; H01L 27/14621

(57) ABSTRACT

The present disclosure relates to a solid-state image capturing device and a manufacturing method as well as an electronic device that are capable of achieving better image quality. A light blocking portion is provided along wall surfaces of a slit defined in an insulating film between adjacent pixels that is provided in covering relation to a light receiving surface of a semiconductor substrate having an element-separating structure between a plurality of pixels. A low-refractive-index wall is provided between light blocking portions between adjacent ones of the pixels and provided between color filters provided above the insulating film. The present technology can be applied to a back-irradiated CMOS image sensor, for example.

### TECHNICAL FIELD

The present disclosure relates to a solid-state image capturing device and a manufacturing method, as well as an electronic device, and more particularly to a solid-state image capturing device and a manufacturing method as well as an electronic device that are capable of achieving better image quality.

### BACKGROUND ART

Heretofore, it has been customary for a solid-state image capturing device such as a CMOS (Complementary Metal Oxide Semiconductor) image sensor to suffer a reduction in image quality in case light that has passed through a color filter of a certain pixel is applied to the photodiode of another pixel adjacent thereto, resulting in a color mixture.

In view of the above problem, there has been proposed an image sensor having a structure in which an interpixel light blocking film including a low-refractive-index wall or the like extends through an anti-reflection film into contact with a trench, thereby restraining a color mixture and a light loss, as disclosed in PTL 1.

### CITATION LIST

### Patent Literature

PTL 1: U.S. Patent Application Publication No. 2020/0083268

### SUMMARY

### Technical Problems

Incidentally, while various structures have been proposed for restraining occurrence of color mixtures between pixels, there have been demands for improving image quality by restraining the occurrence of color mixtures more appropriately.

The present disclosure has been made in view of the above situation and aims at achieving better image quality.

### Solution to Problems

A solid-state image capturing device according to an aspect of the present disclosure includes a semiconductor substrate having an element-separating structure between a plurality of pixels, an insulating film provided in covering relation to a light receiving surface of the semiconductor substrate, and a light blocking portion provided along wall surfaces of a slit arranged between adjacent ones of the pixels in the insulating film.

A method of manufacturing a solid-state image capturing device according to an aspect of the present disclosure includes growing an insulating film in covering relation to a light receiving surface of a semiconductor substrate having an element-separating structure between a plurality of pixels, and forming a light blocking portion along wall surfaces of a slit arranged between adjacent ones of the pixels in the insulating film.

An electronic device according to an aspect of the present disclosure includes a solid- state image capturing device having a semiconductor substrate having an element-separating structure between a plurality of pixels, an insulating film provided in covering relation to a light receiving surface of the semiconductor substrate, and a light blocking portion provided along wall surfaces of a slit arranged between adjacent ones of the pixels in the insulating film.

According to the aspects of the present disclosure, the insulating film is provided in covering relation to the light detecting surface of the semiconductor substrate having the element-separating structure between the plurality of pixels, and the light blocking portion is provided along the wall surfaces of the slit defined in the insulating film between the adjacent ones of the pixels.

### BRIEF DESCRIPTION OF DRAWINGS

FIG. 1 is a block diagram depicting a structural example of a first embodiment of an image capturing device to which the present technology is applied.

FIG. 2 is a view illustrating a method of manufacturing the image capturing device depicted in FIG. 1.

FIG. 3 is a view illustrating the method of manufacturing the image capturing device depicted in FIG. 1.

FIG. 4 is a view illustrating the method of manufacturing the image capturing device depicted in FIG. 1.

FIG. 5 is a view depicting a structural example of a second embodiment of the image capturing device.

FIG. 6 is a view illustrating a method of manufacturing the image capturing device depicted in FIG. 5.

FIG. 7 is a view illustrating the method of manufacturing the image capturing device depicted in FIG. 5.

FIG. 8 is a view illustrating a variation of a line width of a barrier metal layer on a surface of a multilayer insulating film.

FIG. 9 is a view depicting a structural example of a third embodiment of the image capturing device.

FIG. 10 is a view illustrating a variation of a position of an upper end of the barrier metal.

FIG. 11 is a view illustrating a method of manufacturing the image capturing device depicted in FIG. 9.

FIG. 12 is a view depicting a structural example of a fourth embodiment of the image capturing device.

FIG. 13 is a view illustrating a method of manufacturing the image capturing device depicted in FIG. 12.

FIG. 14 is a view illustrating the method of manufacturing the image capturing device depicted in FIG. 12.

FIG. 15 is a view depicting a structural example of a fifth embodiment of the image capturing device.

FIG. 16 is a block diagram depicting a configurational example of an image capturing device.

FIG. 17 is a view depicting examples in which an image sensor is used.

### DESCRIPTION OF EMBODIMENTS

Specific embodiments to which the present technology is applied will hereinafter be described in detail with reference to the drawings.

### First Structural Example of Image Capturing Device

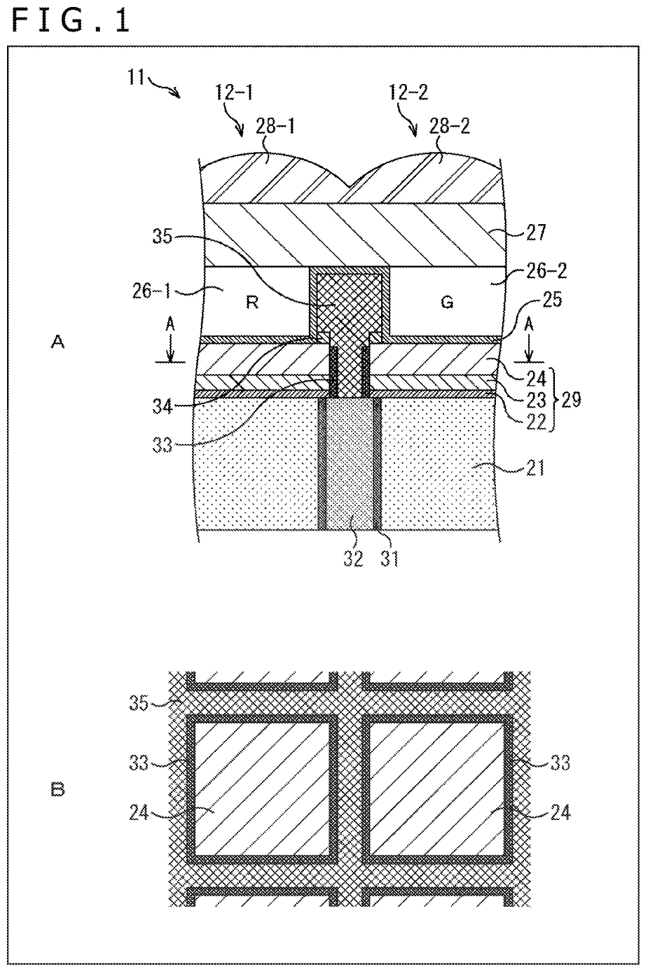

FIG. 1 is a view depicting a structural example of a first embodiment of an image capturing device to which the present technology is applied.

A in FIG. 1 depicts a cross-sectional structural example of an image capturing device 11. B in FIG. 1 depicts a planar structural example of the image capturing device 11 on a cross-sectional plane taken along line A-A of A in FIG. 1. The image capturing device 11 includes a plurality of pixels 12 arranged in a grid. FIG. 1 depicts a structural example of two pixels 12-1 and 12-2 adjacent to each other.

As depicted in A in FIG. 1, the image capturing device 11 includes a laminated assembly of a semiconductor substrate 21, a first aluminum oxide film 22, a hafnium oxide film 23, a silicon oxide film 24, a second aluminum oxide film 25, color filters 26, a planarizing layer 27, and on-chip lenses 28. For example, the image capturing device 11 represents a back-irradiated CMOS image sensor where the semiconductor substrate 21 has a back surface irradiated with light. A multilayer film including the first aluminum oxide film 22, the hafnium oxide film 23, and the silicon oxide film 24 that are laminated on a light detecting surface representing the back surface of the semiconductor substrate 21 is also referred to as a multilayer insulating film 29.

The semiconductor substrate 21 includes a monocrystalline silicon wafer, for example, including a photodiode in each of the pixels 12. The semiconductor substrate 21 includes a trench defined therethrough between adjacent ones of the pixels 12. Silicon oxide films 31 are deposited on respective side surfaces of the trench, which is filled with polysilicon 32. Specifically, the semiconductor substrate 21 includes an element-separating structure that electrically and optically separates the pixels 12 from each other with the silicon oxide films 31 and the polysilicon 32.

The multilayer insulating film 29 that includes the first aluminum oxide film 22, the hafnium oxide film 23, and the silicon oxide film 24 insulates the light detecting surface of the semiconductor substrate 21. The multilayer insulating film 29 has a slit separating adjacent ones of the pixels 12 from each other. A barrier metal layer 33 is disposed along side walls of the slit. The barrier metal layer 33 represents a light blocking portion for blocking light and includes a light blocking metal such as tungsten, aluminum, titanium, titanium nitride, or tantalum, for example.

As depicted in B in FIG. 1, a low-refractive-index wall 35 is provided that fills a gap between the barrier metal layers 33 between adjacent ones of the pixels 12. The low-refractive-index wall 35 may include a material having a lower refractive index than the multilayer insulating film 29, e.g., inorganic film of SiN, SiO₂, SiON, or the like or a resin-based material (organic film) of styrene-based resin, acryl-based resin, styrene-acryl-copolymer-based resin, siloxane-based resin, or the like. The low-refractive-index wall 35 is also provided between the pixels 12 in the color filters 26 that is disposed on an upper surface of the multilayer insulating film 29, for restraining leakage of light from side surfaces of the color filters 26.

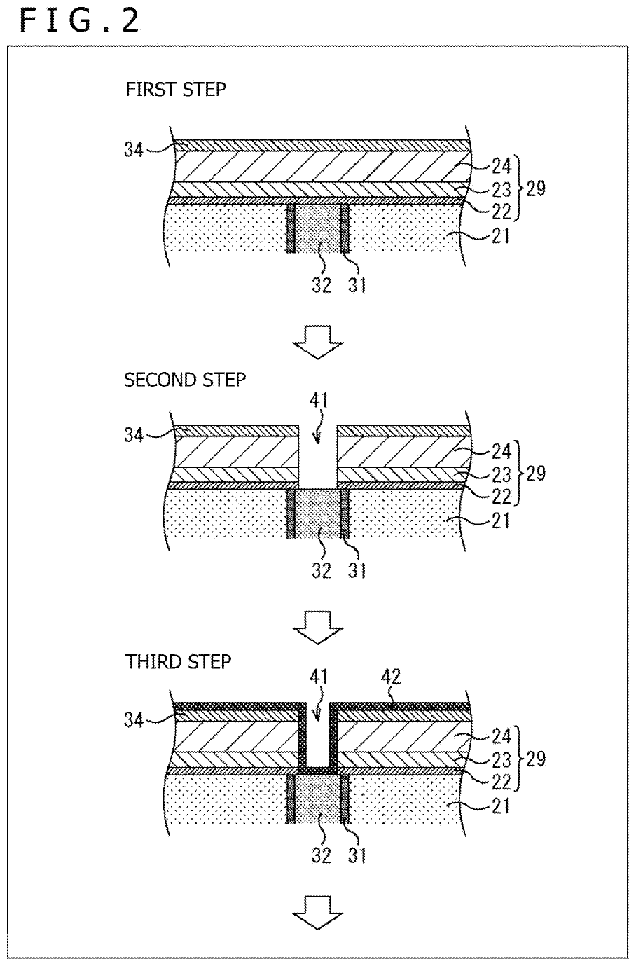

An etching stopper layer 34 having a predetermined line width that extends from ends of the slit in the multilayer insulating film 29 is disposed on the surface of the multilayer insulating film 29 near the slit. As described later with reference to FIGS. 2 through 4, the etching stopper layer 34 represents a remainder (a portion left unremoved in a dry etching process) left after being used as a stopper in a dry etching process for producing the low-refractive-index wall 35 from a low-refractive-index layer 43.

The second aluminum oxide film 25 is provided in covering relation to a surface of the silicon oxide film 24 and surfaces (upper and side surfaces) of the low-refractive-index wall 35.

The color filters 26 transmit light detected by the respective pixels 12. In the illustrated example, a color filter 26-1 transmits red light and a color filter 26-2 transmits green light. The planarizing layer 27 planarizes the surfaces of the color filters 26 and the second aluminum oxide film 25. The on-chip lenses 28 converge light on the respective pixels 12.

In the image capturing device 11 thus configured, the barrier metal layer 33 on the side walls of the slit in the multilayer insulating film 29 blocks light from an adjacent pixel 12, restraining the occurrence of a color mixture for increased image quality. Specifically, the image capturing device 11 is arranged to enable the barrier metal layer 33 to block red light transmitted through the color filter 26-1 of the pixel 12-1 against entry into the pixel 12-2 via the multilayer insulating film 29. For example, the image capturing device 11 is able to restrain the occurrence of a color mixture better than if the bottom surface of the slit in the multilayer insulating film 29 is shielded from light.

A method of manufacturing the image capturing device 11 will be described below with reference to FIGS. 2 through 4.

As depicted in FIG. 2, in a first step, the first aluminum oxide film 22, the hafnium oxide film 23, and the silicon oxide film 24 are grown on the entire light detecting surface of the semiconductor substrate 21 that includes the element-separating structure provided by the silicon oxide films 31 and the polysilicon 32, thereby including the multilayer insulating film 29. Furthermore, the etching stopper layer 34 is laminated on the entire surface of the silicon oxide film 24.

In a second step, the etching stopper layer 34 and the multilayer insulating film 29 are divided to form a slit 41 therein until the surface of the polysilicon 32 is exposed between the pixels 12. Note that the slit 41 may be formed such that its bottom surface lies in the polysilicon 32, i.e., the bottom surface of the slit 41 is positioned below the surface of the semiconductor substrate 21.

In a third step, a metal film 42 that will serve as the barrier metal layer 33 is grown in order to cover the surface of the etching stopper layer 34 and the wall and bottom surfaces of the slit 41. For example, the metal film 42 is formed by growing a titanium nitride alloy (Mo-TiN) according to MO-CVD (Metal Organic Chemical Vapor Deposition).

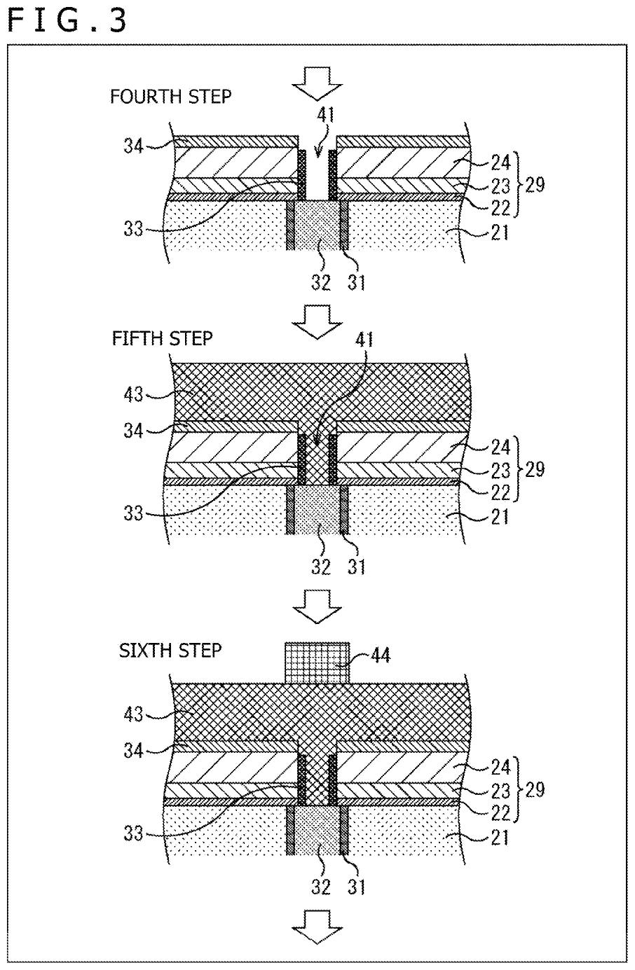

As illustrated in FIG. 3, in a fourth step, the metal film 42 that has covered the surface of the etching stopper layer 34 and the bottom surface of the slit 41 is etched back and removed, leaving the metal film 42 on the side surfaces of the slit 41 as the barrier metal layer 33. At this time, the barrier metal layer 33 has its upper end faces etched to a position lower than the surface of the etching stopper layer 34, as depicted in FIG. 3. However, the upper end faces of the barrier metal layer 33 may alternatively remain at the same height as the surface of the etching stopper layer 34.

In a fifth step, the surface of the assembly is coated with a material having a low refractive index, filling the slit 41 and covering the surface of the etching stopper layer 34 thereby to form a low-refractive-index layer 43 that will provide the low-refractive-index wall 35.

In a sixth step, a photoresist 44 having a pattern corresponding to the planar shape of the low-refractive-index wall 35 is formed on the surface of the low-refractive-index layer 43.

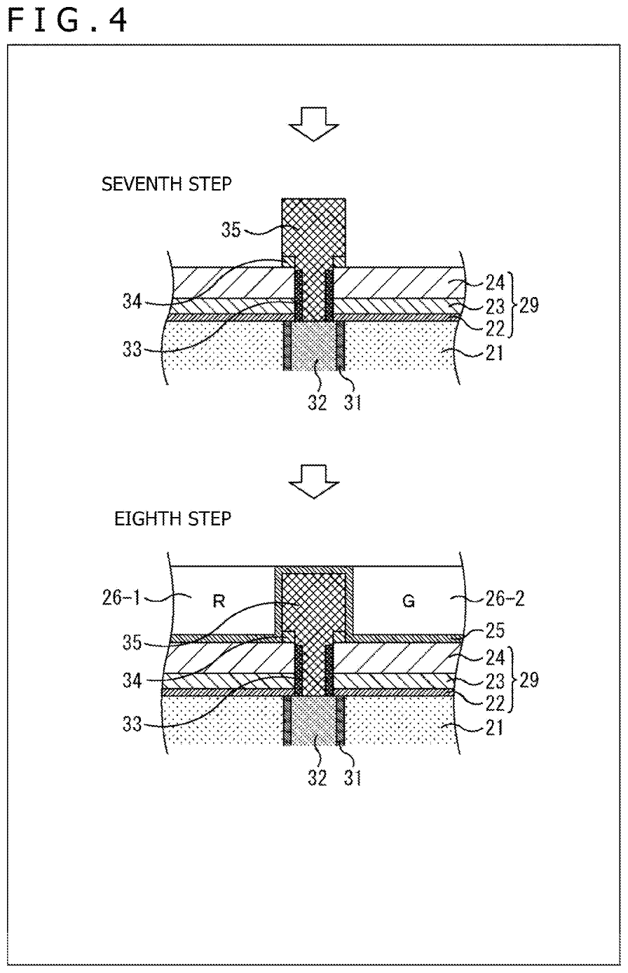

As illustrated in FIG. 4, in a seventh step, a dry etching process is carried out using the photoresist 44 as an etching mask, and thereafter the photoresist 44 is removed, forming the low-refractive-index wall 35. At this time, as the width of the photoresist 44 is larger than the width of the slit 41, portions of the etching stopper layer 34 that lie below the low-refractive-index wall 35 across predetermined line widths from the ends of the slit 41 remain unremoved, whereas the other portions of the etching stopper layer 34 are removed. Alternatively, however, the other portions of the etching stopper layer 34 may remain unremoved.

In an eighth step, the second aluminum oxide film 25 is grown in order to cover the surfaces of the silicon oxide film 24 and the low-refractive-index wall 35, and the color filters 26 of the colors corresponding to the respective pixels 12 are formed.

Thereafter, the planarizing layer 27 is laminated to planarize the surface of the assembly, and the on-chip lenses 28 are formed over the respective pixels 12, thereby manufacturing the image capturing device 11 illustrated in FIG. 1.

The image capturing device 11 in which the barrier metal layer 33 is provided on the side surfaces of the slit 41 defined in the multilayer insulating film 29 is thus manufactured by the steps described above.

### Second Structural Example of Image Capturing Device

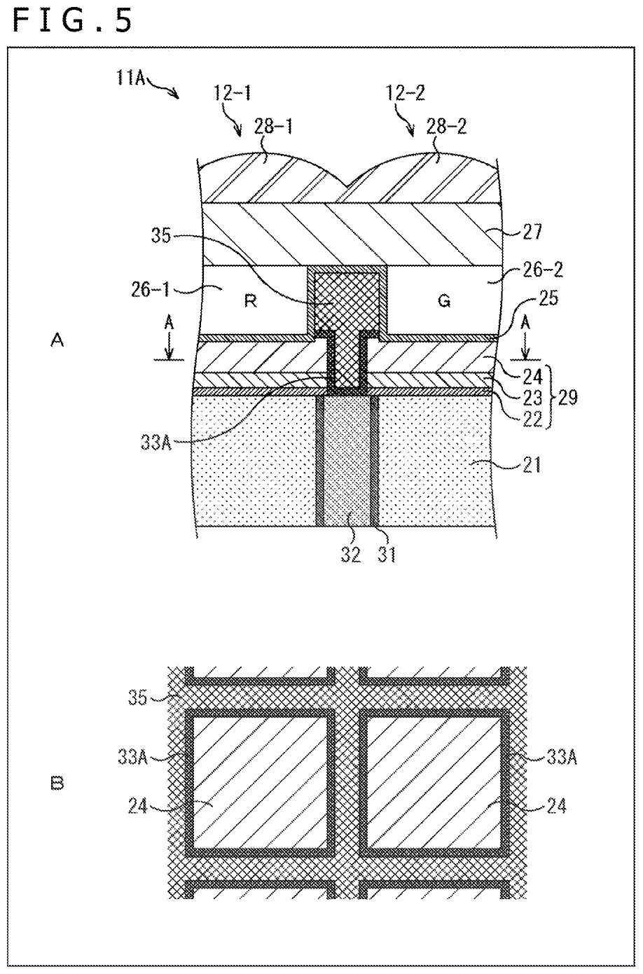

FIG. 5 is a view depicting a structural example of a second embodiment of the image capturing device to which the present technology is applied.

A in FIG. 5 depicts a cross-sectional structural example of an image capturing device 11A. B in FIG. 5 depicts a planar structural example of the image capturing device 11A on a cross-sectional plane taken along line A-A of A in FIG. 5. Note that the image capturing device 11A depicted in FIG. 5 has some parts in common with the image capturing device 11 depicted in FIG. 1, and those parts are denoted by identical reference signs and will be omitted from detailed description.

For example, in common with the image capturing device 11 depicted in FIG. 1, the image capturing device 11A is of such a structure that the semiconductor substrate 21, the multilayer insulating film 29 (the first aluminum oxide film 22, the hafnium oxide film 23, and the silicon oxide film 24), the second aluminum oxide film 25, the color filters 26, the planarizing layer 27, and the on-chip lenses 28 are laminated. Furthermore, in common with the image capturing device 11 depicted in FIG. 1, the image capturing device 11A is of such a structure that the semiconductor substrate 21 includes the element-separating structure provided by the silicon oxide films 31 and the polysilicon 32 and the low-refractive-index wall 35 is provided between the color filters 26 and the multilayer insulating film 29.

Now, the image capturing device 11A has a barrier metal layer 33A that is different in a structure from the barrier metal layer 33 of the image capturing device 11 illustrated in FIG. 1.

As illustrated in FIG. 5, the barrier metal layer 33A is provided along the side walls and bottom surface of the slit defined in the multilayer insulating film 29 between the pixels 12. Specifically, the barrier metal layer 33A is provided between the low-refractive-index wall 35 and the multilayer insulating film 29 and between the low-refractive-index wall 35 and the polysilicon 32. The barrier metal layer 33A has upper ends spreading outwardly on the surface of the multilayer insulating film 29 across predetermined line widths from the ends of the slit 41.

In the image capturing device 11A thus configured, the barrier metal layer 33A on the side walls and bottom surface of the slit in the multilayer insulating film 29 blocks light from an adjacent pixel 12, restraining the occurrence of a color mixture for increased image quality.

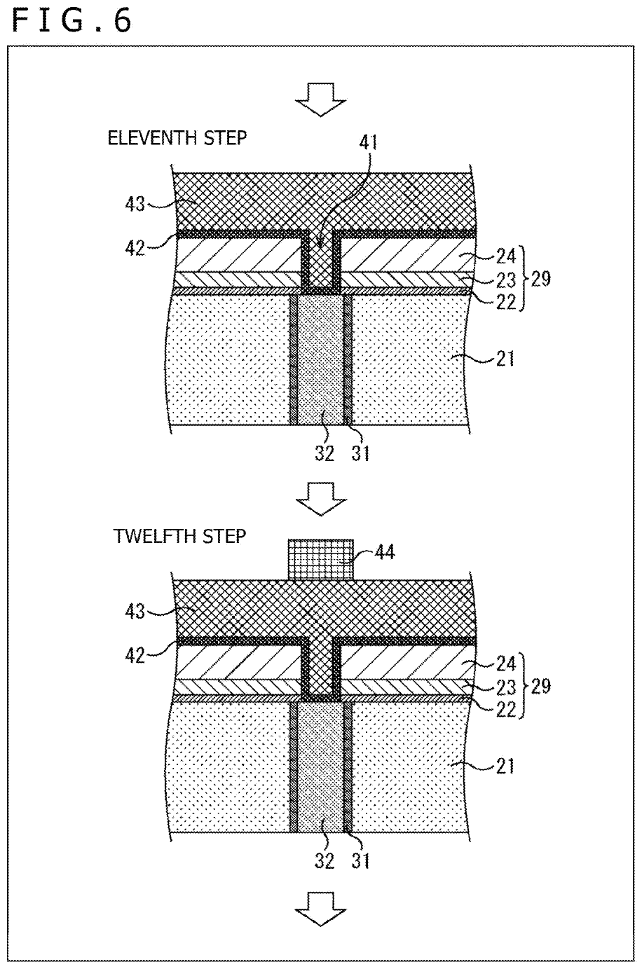

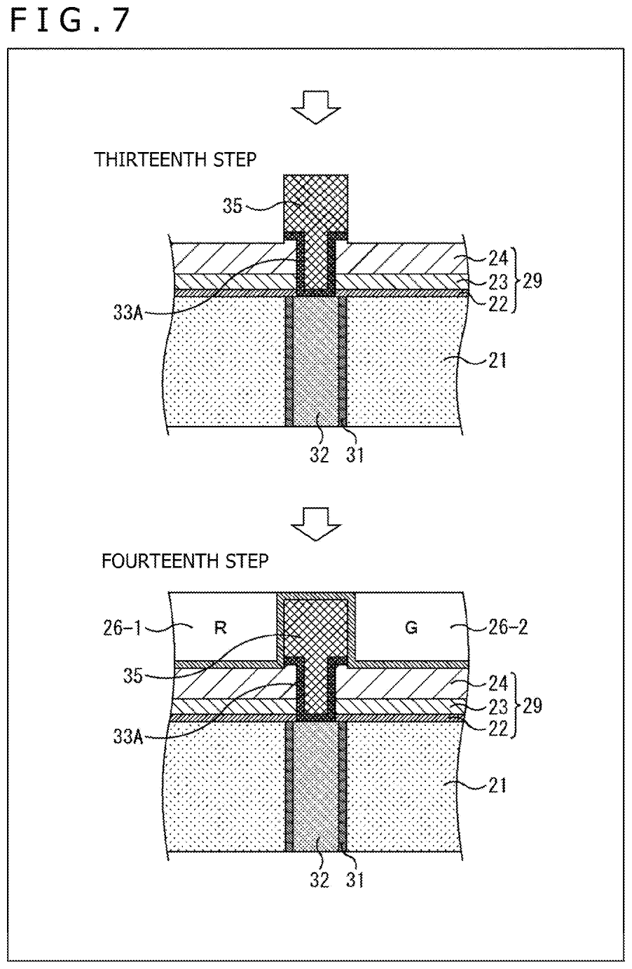

A method of manufacturing the image capturing device 11A will be described below with reference to FIGS. 6 and 7.

For example, as with the first step described above with reference to FIG. 2, the multilayer insulating film 29 is grown on the semiconductor substrate 21, and as with the second step, the slit 41 is formed in the multilayer insulating film 29. Here, the method of manufacturing the image capturing device 11A is different from the method of manufacturing the image capturing device 11 in that the lamination of the etching stopper layer 34 is omitted. Of course, the image capturing device 11A may be manufactured according to a sequence including a step of laminating the etching stopper layer 34.

Thereafter, as illustrated in FIG. 6, in an eleventh step, a metal film 42 that will provide the barrier metal layer 33A is grown in order to cover the surface of the silicon oxide film 24 and the wall and bottom surfaces of the slit 41. Moreover, the surface of the assembly is coated with a material having a low refractive index, filling the slit 41 and covering the surface of the etching stopper layer 34 thereby to form a low-refractive-index layer 43 that will provide the low-refractive-index wall 35.

In a twelfth step, a photoresist 44 having a pattern corresponding to the planar shape of the low-refractive-index wall 35 is formed on the surface of the low-refractive-index layer 43.

As illustrated in FIG. 7, in a thirteenth step, a dry etching process is carried out using the photoresist 44 as an etching mask, and thereafter the photoresist 44 is removed, forming the barrier metal layer 33A and the low-refractive-index wall 35. At this time, as the metal film 42 on the surface of the silicon oxide film 24 is removed, the surface of the silicon oxide film 24 is slightly removed by the dry etching process, as illustrated in FIG. 7.

In a fourteenth step, the second aluminum oxide film 25 is grown in covering relation to the surfaces of the silicon oxide film 24 and the low-refractive-index wall 35, and the color filters 26 of the colors corresponding to the respective pixels 12 are formed.

Thereafter, the planarizing layer 27 is laminated to planarize the surface of the assembly, and the on-chip lenses 28 are formed over the respective pixels 12, thereby manufacturing the image capturing device 11A illustrated in FIG. 5.

The image capturing device 11A in which the barrier metal layer 33A is provided on the side surfaces and bottom surface of the slit 41 defined in the multilayer insulating film 29 is thus manufactured by the steps described above.

Note that the dry etching process that is carried out in the thirteenth step illustrated in FIG. 7 is not limited to forming the barrier metal layer 33A such that the line widths of the barrier metal layer 33A remaining on the surface of the silicon oxide film 24 are aligned with the side surfaces of the low-refractive-index wall 35.

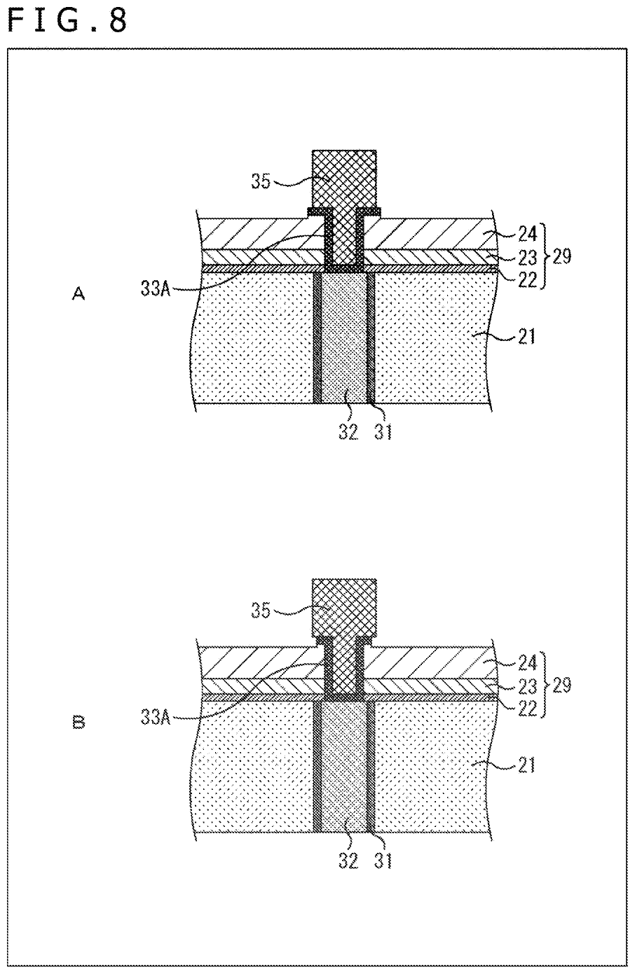

For example, as illustrated in A in FIG. 8, the barrier metal layer 33A may be formed such that the line widths of the barrier metal layer 33A remaining on the surface of the silicon oxide film 24 are larger outwardly than the side surfaces of the low-refractive-index wall 35. Alternatively, as illustrated in B in FIG. 8, the barrier metal layer 33A may be formed such that the line widths of the barrier metal layer 33A remaining on the surface of the silicon oxide film 24 are smaller inwardly than the side surfaces of the low-refractive-index wall 35.

### Third Structural Example of Image Capturing Device

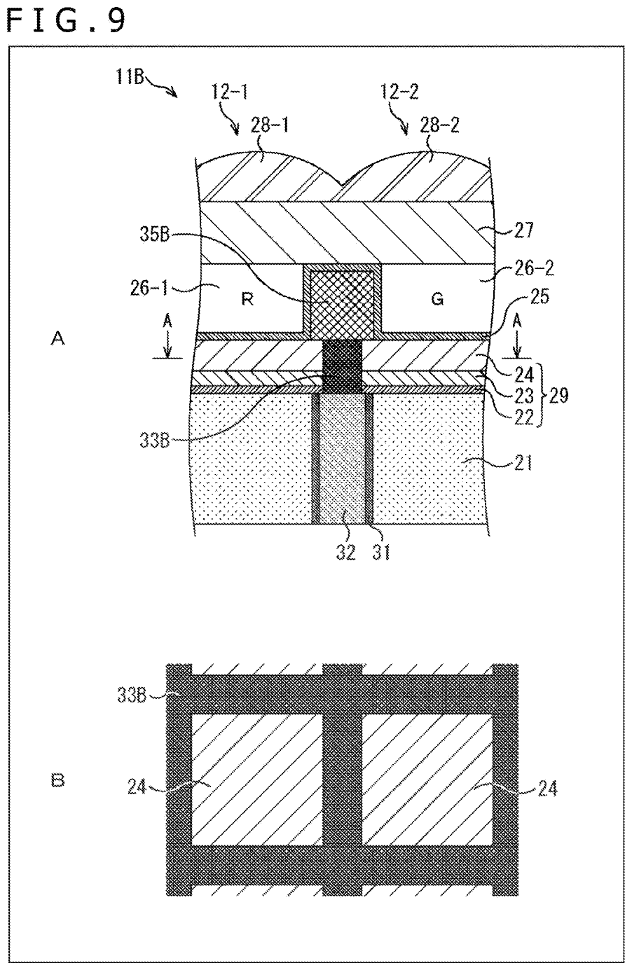

FIG. 9 is a view depicting a structural example of a third embodiment of the image capturing device to which the present technology is applied.

A in FIG. 9 depicts a cross-sectional structural example of an image capturing device 11B. B in FIG. 9 depicts a planar structural example of the image capturing device 11B on a cross-sectional plane taken along line A-A of A in FIG. 9. Note that the image capturing device 11B depicted in FIG. 9 has some parts in common with the image capturing device 11 depicted in FIG. 1, and those parts are denoted by identical reference signs and will be omitted from detailed description.

For example, in common with the image capturing device 11 depicted in FIG. 1, the image capturing device 11B is of such a structure that the semiconductor substrate 21, the multilayer insulating film 29 (the first aluminum oxide film 22, the hafnium oxide film 23, and the silicon oxide film 24), the second aluminum oxide film 25, the color filters 26, the planarizing layer 27, and the on-chip lenses 28 are laminated. Furthermore, in common with the image capturing device 11 depicted in FIG. 1, the image capturing device 11B is of such a structure that the semiconductor substrate 21 includes the element-separating structure provided by the silicon oxide films 31 and the polysilicon 32.

The image capturing device 11B includes a barrier metal layer 33B and a low-refractive-index wall 35B that are different in a structure from the barrier metal layer 33 and the low-refractive-index wall 35 of the image capturing device 11 illustrated in FIG. 1.

As illustrated in FIG. 9, the barrier metal layer 33B is provided to fill the slit defined in the multilayer insulating film 29 between the pixels 12 and the low-refractive-index wall 35B is provided between the color filters 26. Specifically, the barrier metal layer 33B alone is provided to be embedded in the multilayer insulating film 29 between the pixels 12.

In the image capturing device 11B thus configured, the barrier metal layer 33B in the slit in the multilayer insulating film 29 blocks light from an adjacent pixel 12, restraining the occurrence of a color mixture for increased image quality.

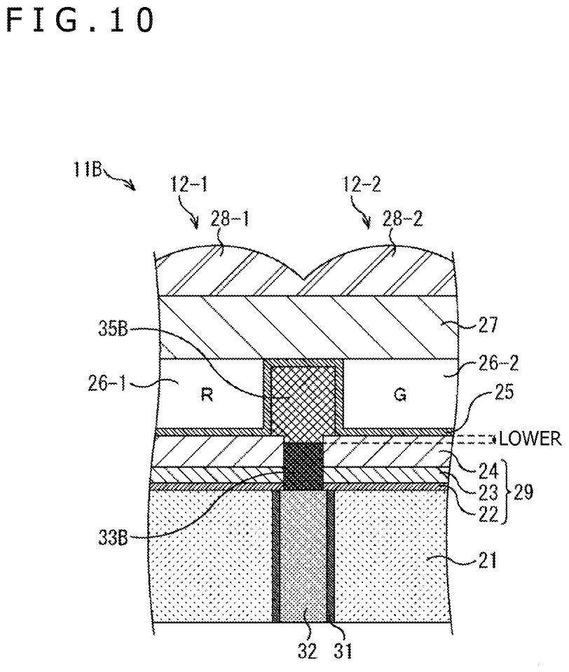

Incidentally, in the image capturing device 11B illustrated in FIG. 9, the upper ends of the barrier metal layer 33B is positionally aligned with the surface of the multilayer insulating film 29. However, the present invention is not limited to such a structure. For example, as illustrated in FIG. 10, the image capturing device 11B may be arranged such that upper ends of the barrier metal layer 33B is positionally lower than the surface of the multilayer insulating film 29.

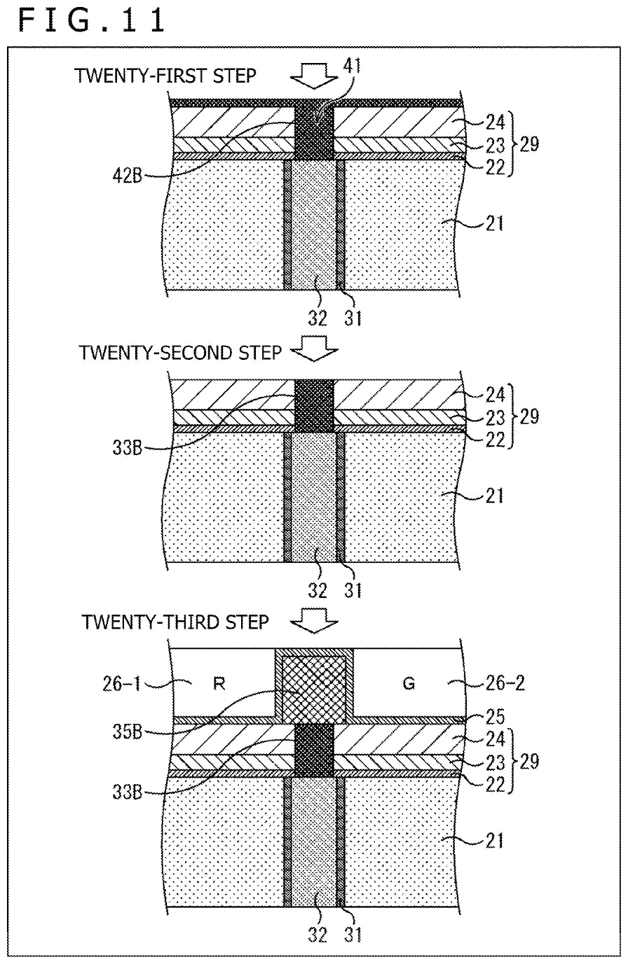

A method of manufacturing the image capturing device 11B will be described below with reference to FIG. 11.

For example, as with the first step described above with reference to FIG. 2, the multilayer insulating film 29 is grown on the semiconductor substrate 21, and as with the second step, the slit 41 is formed in the multilayer insulating film 29. Here, the method of manufacturing the image capturing device 11B is different from the method of manufacturing the image capturing device 11 in that the lamination of the etching stopper layer 34 is omitted. Of course, the image capturing device 11B may be manufactured according to a sequence including a step of laminating the etching stopper layer 34.

Thereafter, as illustrated in FIG. 11, in a twenty-first step, a metal film 42B that will provide the barrier metal layer 33B is grown in order to cover the surface of the silicon oxide film 24 and fill the slit 41.

In a twenty-second step, the metal film 42B covering the surface of the silicon oxide film 24 is removed by CMP (Chemical Mechanical Polishing) or dry etching, forming the barrier metal layer 33B.

Then, as with the fifth through seventh steps described above, the low-refractive-index layer 43 is formed, and a dry etching process is carried out using the photoresist 44 as an etching mask, forming the low-refractive-index wall 35B.

In a twenty-third step, the second aluminum oxide film 25 is grown in order to cover the surfaces of the silicon oxide film 24 and the low-refractive-index wall 35B, and the color filters 26 of the colors corresponding to the respective pixels 12 are formed.

Thereafter, the planarizing layer 27 is laminated to planarize the surface of the assembly, and the on-chip lenses 28 are formed over the respective pixels 12, thereby manufacturing the image capturing device 11B illustrated in FIG. 9.

The image capturing device 11B in which the barrier metal layer 33B is provided to fill the slit 41 defined in the multilayer insulating film 29 is thus manufactured by the steps described above.

### Fourth Structural Example of Image Capturing Device

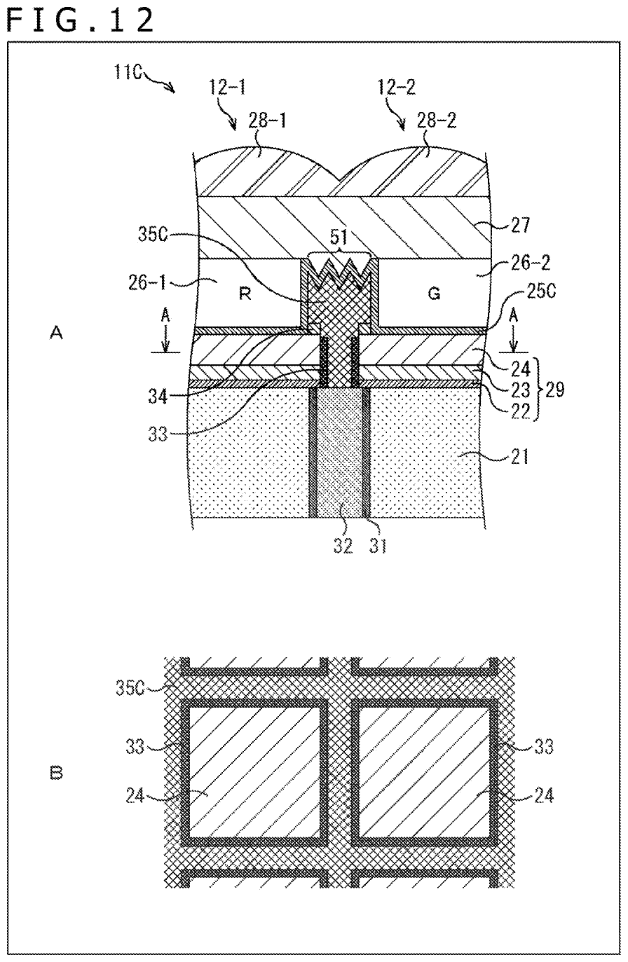

FIG. 12 is a view depicting a structural example of a fourth embodiment of the image capturing device to which the present technology is applied.

A in FIG. 12 depicts a cross-sectional structural example of an image capturing device 11C. B in FIG. 12 depicts a planar structural example of the image capturing device 11C on a cross-sectional plane taken along line A-A of A in FIG. 12. Note that the image capturing device 11C depicted in FIG. 12 has some parts in common with the image capturing device 11 depicted in FIG. 1, and those parts are denoted by identical reference signs and will be omitted from detailed description.

For example, in common with the image capturing device 11 depicted in FIG. 1, the image capturing device 11C is of such a structure that the semiconductor substrate 21, the multilayer insulating film 29 (the first aluminum oxide film 22, the hafnium oxide film 23, and the silicon oxide film 24), a second aluminum oxide film 25C, the color filters 26, the planarizing layer 27, and the on-chip lenses 28 are laminated. Furthermore, in common with the image capturing device 11 depicted in FIG. 1, the image capturing device 11C is of such a structure that the semiconductor substrate 21 includes the element-separating structure provided by the silicon oxide films 31 and the polysilicon 32 and the barrier metal layer 33 is provided along the side walls of the slit defined in the multilayer insulating film 29.

Now, the image capturing device 11C has a low-refractive-index wall 35C that is different in planar shape from the low-refractive-index wall 35 of the image capturing device 11 illustrated in FIG. 1.

As illustrated in FIG. 12, the low-refractive-index wall 35C has, in its upper surface, a concavo-convex structure 51 including a plurality of minute concavities and convexities. The second aluminum oxide film 25C is provided along the shape of the concavo-convex structure 51 in the upper surface of the low-refractive-index wall 35C.

For example, the concavo-convex structure 51 in the upper surface of the low-refractive-index wall 35C can restrain the reflection of light from the interface between the planarizing layer 27 and the low-refractive-index wall 35C. With the concavo-convex structure 51, the image capturing device 11C is able to restrain the occurrence of a flare that would otherwise be caused by the reflection of such light.

In the image capturing device 11C thus configured, the barrier metal layer 33 on the side walls of the slit in the multilayer insulating film 29 blocks light from an adjacent pixel 12, restraining the occurrence of a color mixture, and restrains the occurrence of a flare for increased image quality.

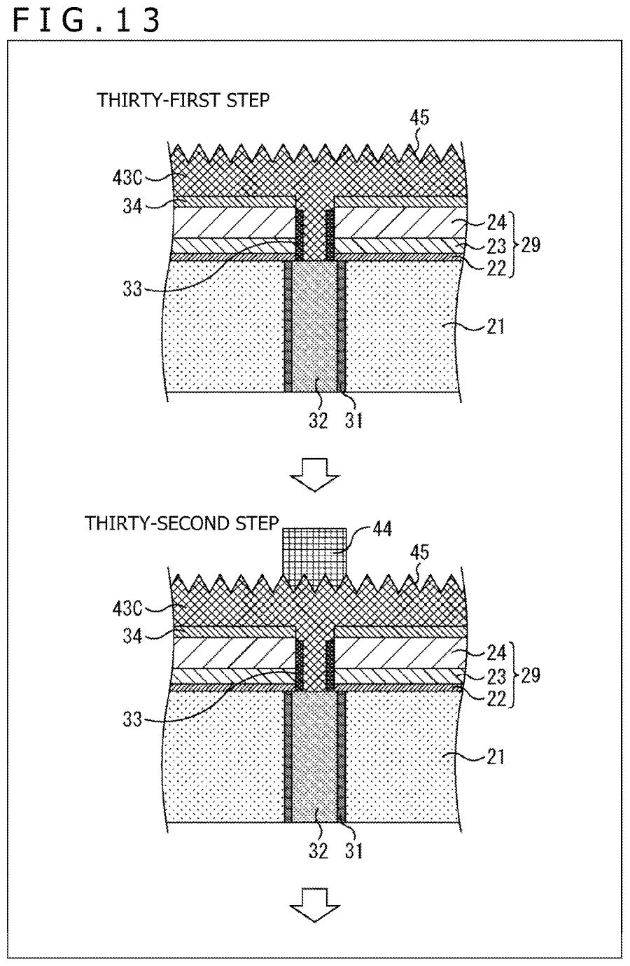

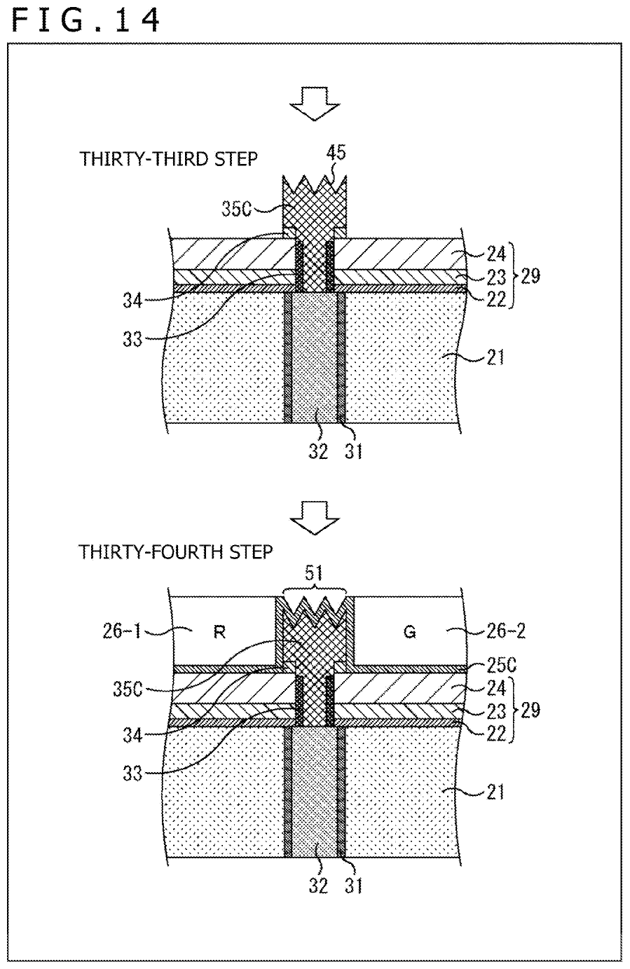

A method of manufacturing the image capturing device 11C will be described below with reference to FIGS. 13 and 14.

For example, the method of manufacturing the image capturing device 11C is carried out in the same manner as with the method of manufacturing the image capturing device 11 in the first through fifth steps described above with reference to FIGS. 2 and 3, forming the low-refractive-index layer 43 having a flat surface that fills the slit 41 where the barrier metal layer 33 has been formed on the wall surfaces thereof and that covers the surface of the etching stopper layer 34.

Thereafter, as illustrated in FIG. 13, the flat surface of the low-refractive-index layer 43 is processed into a low-refractive-index layer 43C having a concavo-convex surface 45. The concavo-convex surface 45 of the low-refractive-index layer 43C can be formed by an etching process that involves miniscule patterning using a self-assembly material, for example. In a thirty-second step, a photoresist 44 having a pattern corresponding to the planar shape of the low-refractive-index wall 35C is formed on the concavo-convex surface 45 of the low-refractive-index layer 43C.

As illustrated in FIG. 14, in a thirty-third step, a dry etching process is carried out using the photoresist 44 as an etching mask, and thereafter the photoresist 44 is removed, forming the low-refractive-index wall 35C.

In a thirty-fourth step, the second aluminum oxide film 25C is grown in order to cover the surfaces of the silicon oxide film 24 and the low-refractive-index wall 35C. At this time, the second aluminum oxide film 25C is grown along the shape of the concavo-convex structure 51 of the low-refractive-index wall 35C. Then, the color filters 26 of the colors corresponding to the respective pixels 12 are formed.

Thereafter, the planarizing layer 27 is laminated to planarize the surface of the assembly, and the on-chip lenses 28 are formed over the respective pixels 12, thereby manufacturing the image capturing device 11C illustrated in FIG. 12.

The image capturing device 11C in which the barrier metal layer 33 is provided on the side surfaces of the slit 41 defined in the multilayer insulating film 29 and the low-refractive-index wall 35C with the concavo-convex structure 51 formed on its upper surface is provided is thus manufactured by the steps described above.

### Fifth Structural Example of Image Capturing Device

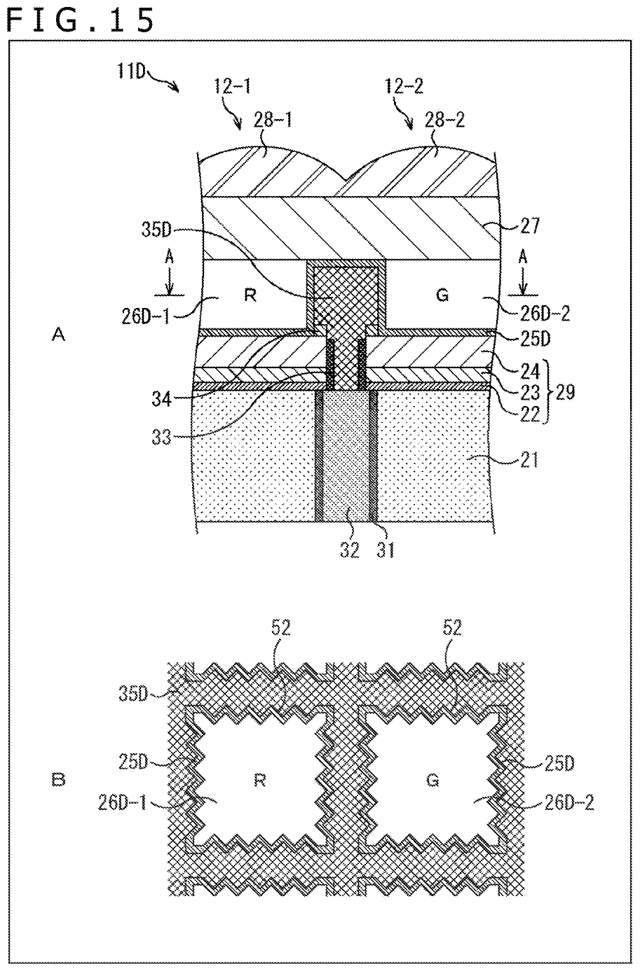

FIG. 15 is a view depicting a structural example of a fifth embodiment of the image capturing device to which the present technology is applied.

A in FIG. 15 depicts a cross-sectional structural example of an image capturing device 11D. B in FIG. 15 depicts a planar structural example of the image capturing device 11D on a cross-sectional plane taken along line A-A of A in FIG. 15. Note that the image capturing device 11D depicted in FIG. 15 has some parts in common with the image capturing device 11 depicted in FIG. 1, and those parts are denoted by identical reference signs and will be omitted from detailed description.

For example, in common with the image capturing device 11 depicted in FIG. 1, the image capturing device 11D is of such a structure that the semiconductor substrate 21, the multilayer insulating film 29 (the first aluminum oxide film 22, the hafnium oxide film 23, and the silicon oxide film 24), a second aluminum oxide film 25D, color filters 26D, the planarizing layer 27, and the on-chip lenses 28 are laminated. Furthermore, in common with the image capturing device 11 depicted in FIG. 1, the image capturing device 11D is of such a structure that the semiconductor substrate 21 includes the element-separating structure provided by the silicon oxide films 31 and the polysilicon 32 and the barrier metal layer 33 is provided along the side walls of the slit defined in the multilayer insulating film 29.

Now, the image capturing device 11D has a low-refractive-index wall 35D, and the low-refractive-index wall 35D and the color filters 26D have side surfaces that are different in shape from the low-refractive-index wall 35 and the color filters 26 of the image capturing device 11 illustrated in FIG. 1.

As illustrated in B in FIG. 15, the low-refractive-index wall 35D and the color filters 26D have, in their side surfaces, a concavo-convex structure 52 including a plurality of minute concavities and convexities. The second aluminum oxide film 25D is provided along the shape of the concavo-convex structures 52 in the side surfaces of the low-refractive-index wall 35D.

The concavo-convex structures 52 in the side surfaces of the low-refractive-index wall 35D can restrain the reflection of light from the interface between the color filters 26D and the low-refractive-index wall 35D. With the concavo-convex structure 52, the image capturing device 11D is able to restrain the occurrence of a flare that would otherwise be caused by the reflection of such light. In particular, the image capturing device 11D is effective in restraining the occurrence of a flare in peripheral pixels where the chief ray angle (CRA) of light rays applied obliquely is high.

Incidentally, the image capturing device 11D can be combined with either one of the image capturing devices 11 through 11D according to the embodiments described above.

### Configurational Examples of Electronic Device

The image capturing device 11 described above may be applied to various electronic devices including image capturing systems such as digital still cameras and digital video cameras, cellar phones having an image capturing function, and other devices having an image capturing function.

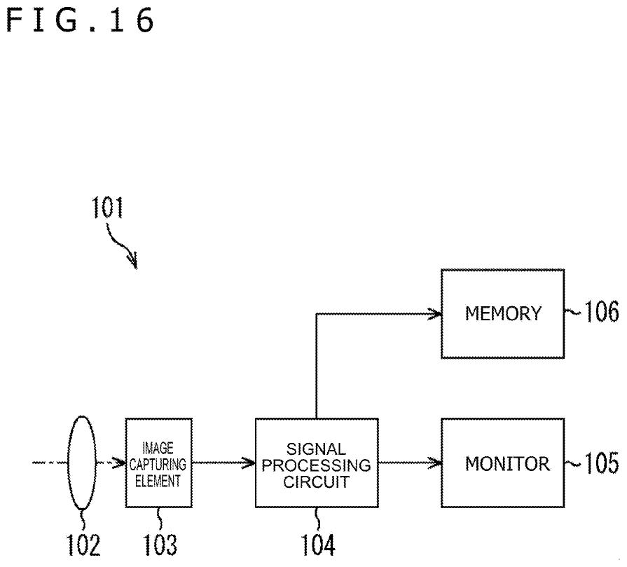

FIG. 16 is a block diagram depicting a configurational example of an image capturing apparatus incorporated in an electronic device.

As illustrated in FIG. 16, an image capturing apparatus 101 includes an optical system 102, an image capturing element 103, a signal processing circuit 104, a monitor 105, and a memory 106, and is able to capture still images and moving images.

The optical system 102 has a single lens or a plurality of lenses, and introduces image light (incident light) from a subject into the image capturing element 103 where the image light is focused on a light detecting surface (sensor) of the image capturing element 103.

The image capturing device 11 described above is applied to the image capturing element 103. The image capturing element 103 stores electrons for a certain period of time depending on the image that is focused via the optical system 102 onto the light detecting surface. Then, the image capturing element 103 supplies signals depending on the electrons stored therein to the signal processing circuit 104.

The signal processing circuit 104 performs various signal processing processes on pixel signals output from the image capturing element 103. Images (image data) obtained by the signal processing processes performed by the signal processing circuit 104 are supplied to the monitor 105 where they are displayed or supplied to the memory 106 where they are stored (recorded).

The image capturing apparatus 101 thus configured is able to capture images of higher quality because the image capturing device 11 is incorporated therein, for example.

### Examples in Which an Image Sensor is Used

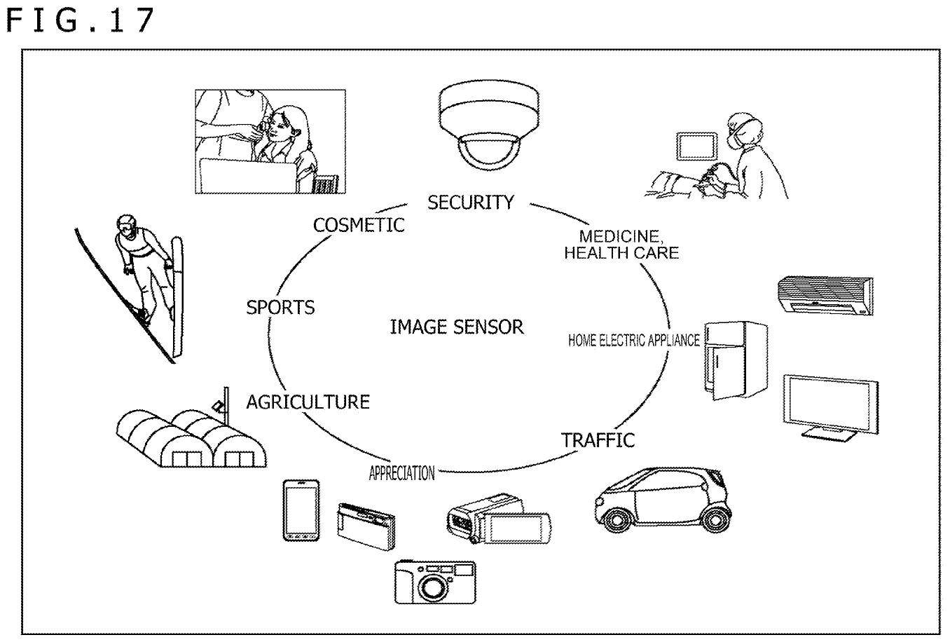

FIG. 17 is a view depicting examples in which the above image sensor (image capturing device) is used.

The above image sensor can be used in various cases where visible light, infrared light, ultraviolet light, X-rays, etc. are sensed, for example, as follows.
Devices for capturing images to be observed for appreciation such as digital cameras and portable devices with a camera function.
Devices for use in connection with traffic, such as vehicle-mounted sensors for capturing images forward and rearward of, around, and in cars, monitoring cameras for monitoring traveling vehicles and roads, ranging sensors for measuring distances between vehicles, in order to ensure safety driving including automatic vehicle halting, etc. and recognize driver's states, etc.
Devices for use in home electric appliances including TVs, refrigerators, air conditioners, etc. for capturing images of user's gestures and controlling appliance operations according to the captured gesture images.
Devices for use in medical and health care applications such as endoscopes and angiographic devices based on detection of infrared light.
Devices for use in connection with security such as monitoring cameras used for crime prevention and cameras used for personal authentication.
Devices for use in connection with cosmetic applications such as skin measuring instruments for capturing images of skin and microscopes for capturing images of scalps.
Devices for use in sports such as action cameras and wearable cameras used for sports applications.
Devices for use in agricultural applications such as cameras for monitoring states of farms and crops.

### Examples of Combinations of Configurations

Incidentally, the present technology may be implemented by way of the following configurations.

(1)

A solid-state image capturing device including:
a semiconductor substrate having an element-separating structure between a plurality of pixels;
an insulating film provided in covering relation to a light receiving surface of the semiconductor substrate; and
a light blocking portion provided along wall surfaces of a slit arranged between adjacent ones of the pixels in the insulating film.
   (2)

The solid-state image capturing device according to (1) above, in which the light blocking portion is disposed along the wall surfaces and a bottom surface of the slit.

(3)

The solid-state image capturing device according to (1) above, in which the light blocking portion is provided to fill the slit.

(4)

The solid-state image capturing device according to any one of (1) to (3) above, further including:
a low-refractive-index wall provided between the light blocking portions between adjacent ones of the pixels and provided between color filters disposed above the insulating film.
   (5)

The solid-state image capturing device according to (4) above, in which the low-refractive-index wall has, in an upper surface thereof, a concavo-convex structure including a plurality of minute concavities and convexities.

(6)

The solid-state image capturing device according to (4) above, in which the low-refractive-index wall and the color filters have, in side surfaces thereof, a concavo-convex structure including a plurality of minute concavities and convexities.

(7)

A method of manufacturing a solid-state image capturing device, including:
growing an insulating film in covering relation to a light receiving surface of a semiconductor substrate having an element-separating structure between a plurality of pixels; and
forming a light blocking portion along wall surfaces of a slit arranged between adjacent ones of the pixels in the insulating film.
   (8)

An electronic device including:
a solid-state image capturing device including
   a semiconductor substrate having an element-separating structure between a plurality of pixels,
   an insulating film provided in covering relation to a light receiving surface of the semiconductor substrate, and
   a light blocking portion provided along wall surfaces of a slit arranged between adjacent ones of the pixels in the insulating film.

Note that the embodiments described above are not restrictive, and various changes and modifications may be made therein without departing from the scope of the present disclosure. The advantages referred to above in the present description are by way of example only and are not restrictive, as there may arise other advantages.

### REFERENCE SIGNS LIST

11: Image capturing device
12: Pixel
21: Semiconductor substrate
22: First aluminum oxide film
23: Hafnium oxide film
24: Silicon oxide film
25: Second aluminum oxide film
26: Color filter
27: Planarizing layer
28: On-chip lens
29: Multilayer insulating film
31: Silicon oxide film
32: Polysilicon
33: Barrier metal layer
34: Etching stopper layer
35: Low-refractive-index wall
41: Slit
42: Metal film
43: Low-refractive-index layer
44: Photoresist
45: Concavo-convex surface
51 and 52: Concavo-convex structure.

What is claimed is:

1. A solid-state image capturing device, comprising:
a semiconductor substrate having an element-separating structure between a plurality of pixels;
an insulating film provided in covering relation to a light receiving surface of the semiconductor substrate; and
a light blocking portion provided along wall surfaces of a slit arranged between adjacent ones of the pixels in the insulating film.

2. The solid-state image capturing device according to claim 1, wherein the light blocking portion is disposed along the wall surfaces and a bottom surface of the slit.

3. The solid-state image capturing device according to claim 1, wherein the light blocking portion is provided to fill the slit.

4. The solid-state image capturing device according to claim 1, further comprising:
a low-refractive-index wall provided between the light blocking portions between adjacent ones of the pixels and provided between color filters disposed above the insulating film.

5. The solid-state image capturing device according to claim 4, wherein the low-refractive-index wall has, in an upper surface thereof, a concavo-convex structure including a plurality of minute concavities and convexities.

6. The solid-state image capturing device according to claim 4, wherein the low-refractive-index wall and the color filters have, in side surfaces thereof, a concavo-convex structure including a plurality of minute concavities and convexities.

7. A method of manufacturing a solid-state image capturing device, comprising:
growing an insulating film in covering relation to a light receiving surface of a semiconductor substrate having an element-separating structure between a plurality of pixels; and
forming a light blocking portion along wall surfaces of a slit arranged between adjacent ones of the pixels in the insulating film.

8. An electronic device, comprising:
a solid-state image capturing device including
a semiconductor substrate having an element-separating structure between a plurality of pixels,
an insulating film provided in covering relation to a light receiving surface of the semiconductor substrate, and
a light blocking portion provided along wall surfaces of a slit arranged between adjacent ones of the pixels in the insulating film.
